(19) United States
(12) Patent Application Publication
(10) Pub. No.: US 2008/0282535 A1
(43) Pub. Date: Nov. 20, 2008

(54) METHOD OF FABRICATING AN INTEGRATED CIRCUIT

(75) Inventors: Jonas Sundqvist, Dresden (DE); Frank Koestner, Dresden (DE); Bernd Hintze, Langebrueck (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/748,883

(22) Filed: May 15, 2007

(51) Int. Cl. H05K 3/10

(52) U.S. Cl. 29/846; 29/831

(57) ABSTRACT

A method of fabricating an integrated circuit, including a functional layer on a substrate is disclosed. One embodiment includes providing a substrate in a process atmosphere. A first precursor and a second precursor are provided in the process atmosphere. The first precursor is removed from the process atmosphere. A third precursor is provided in the process atmosphere.

### BACKGROUND

Demands imposed on large scale integrated circuits, such as electronic memory devices, micro-processors, signal-processors, and integrated logic devices, are constantly increasing. In the case of electronic memory devices, those demands mainly translate into enlarging storage capacity and into increasing access speed. As far as modern memory devices are concerned, the computer industry has established, amongst others, the so called DRAM (dynamic random access memory) as an economic means for high speed and high capacity data storage.

Although a DRAM requires continuous refreshing of stored information, speed and information density, combined with a relatively low-cost, have put the DRAM to a pivotal position in the field of information technology. Almost every type of computer system, ranging, for example, from PDAs over notebook computers and personal computers to high end servers, takes advantage of this economic and fast data storage technology. Nevertheless, the computer and electronic industry develops alternatives to the DRAM, such as phase change RAM (PC-RAM), conductive bridging RAM (CB-RAM) and magnetic resistive RAM (M-RAM). Other concepts include the so called flash RAM or static RAM (S-RAM), which have already found their established applications.

Since electronic data storage is so ubiquitous, intense industrial and scientific research and development is aimed at optimizing manufacturing processes, increasing process yield, and maximizing device reliability. As a result, there is a need to improve functional elements of integrated electronic devices to meet recent requirements, such as imposed by large scale mass production.

For these and other reasons, there is a need for the present invention.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1A illustrates a schematic view of an arrangement having a functional layer according to a first embodiment.

FIG. 1B illustrates a schematic view of an arrangement having a functional layer according to a second embodiment.

FIG. 1C illustrates a schematic view of an arrangement having a functional layer according to a third embodiment.

FIG. 1D illustrates a schematic view of an arrangement having a functional layer according to a fourth embodiment.

FIG. 1E illustrates a schematic view of an arrangement having a functional layer according to a fifth embodiment.

FIGS. 2A through 2D illustrate a functional layer in various stages during fabrication according to a sixth embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Various embodiments provide an improved method of fabricating an integrated device, including fabricating a functional layer.

One embodiment provides a method of making an integrated circuit including fabricating a functional layer on a substrate. The method includes providing a substrate in a process atmosphere. A first precursor and a second precursor are provided in the process atmosphere. The first precursor is removed from the process atmosphere. The second precursor is removed from the process atmosphere. A third precursor is provided in the process atmosphere.

One embodiment provides a method of fabricating a functional layer on a substrate. The method includes providing a substrate in a process atmosphere. A first precursor and a second precursor are provided in the process atmosphere. The first precursor is removed from the process atmosphere. A third precursor is provided in the process atmosphere.

These above recited features of the present invention will become clear from the following description, taken in conjunction with the accompanying drawings. It is to be noted, however, that the accompanying drawings illustrate only typical embodiments of the present invention and are, therefore, not to be considered limiting of the scope of the invention. The present invention may admit equally effective embodiments.

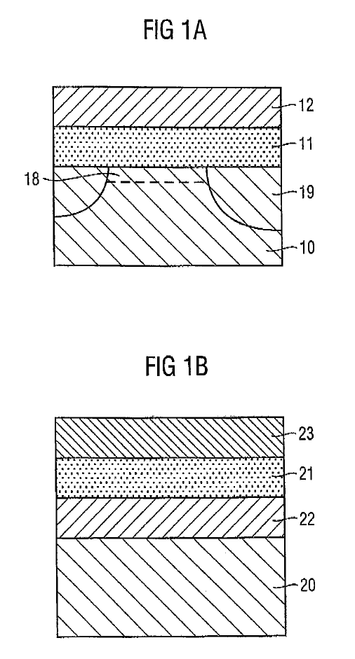

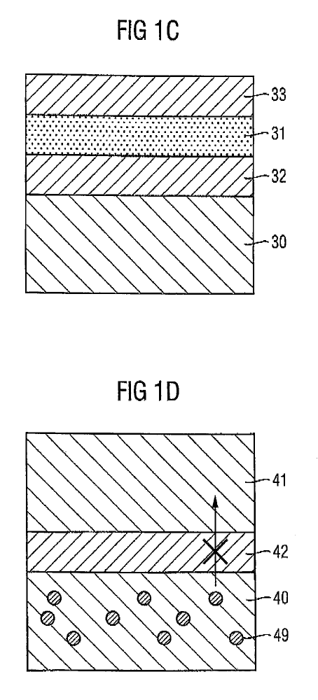

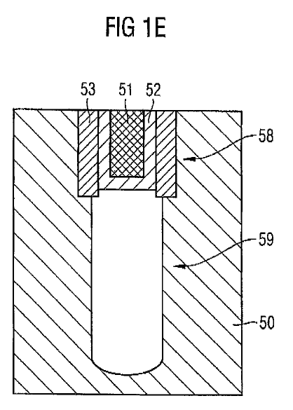

FIG. 1A illustrates a schematic view of an integrated device or integrated circuit including an arrangement having a functional layer according to a first embodiment. In one embodiment, the arrangement part of a transistor and includes a substrate 10, an intermediate layer 11, and a functional layer 12. The intermediate layer 11, for example, may include a dielectric material or insulating material. The functional layer 12 may include a conductive material and/or an electrode material, and may act as a transistor gate electrode according to this embodiment. The substrate 10 may include a semiconductor substrate, such as silicon, and may further include doped regions 19 and/or a transistor channel 18. A current through the transistor channel 18 from one doped region 19 to another doped region 19 may be controlled by the application of an electric signal at the functional layer 12. The dielectric properties of the intermediated layer 11 may further influence, in conjunction with the applied electric signal, the conductivity of the transistor channel 18.

FIG. 1B illustrates an arrangement with a functional layer according to a second embodiment of the present invention. According to this embodiment, a functional layer 22 is arranged on a substrate 20. On the functional layer 22 there is arranged an intermediated layer 21 and an electrode layer 23. The arrangement, as illustrated in FIG. 1B, may be viewed as a capacitor. The capacitor is arranged on a substrate 20, which may include a semiconductor substrate, such as a silicon substrate. The arrangement functional layer 22—intermediate layer 21—electrode layer 23 represents an exemplary capacitor structure, hence the functional layer 22 may act as a capacitor electrode in this embodiment. A voltage applied to the functional layer 22 and to the electrode layer 23 provokes an electric field inside the intermediate layer 21. The dielectric properties of the intermediate layer 21 may affect, amongst other factors, the capacity of the capacitor structure.

FIG. 1C illustrates an arrangement with a functional layer according to a third embodiment. According to this embodiment, a first functional layer 32 is arranged on a substrate 30. On the functional layer 32 there is arranged an intermediated layer 31 and a second functional layer 33. The arrangement, as illustrated in FIG. 1C, may be viewed as a capacitor, hence the first functional layer 32 and the second functional layer 33 may act as capacitor electrodes according to this embodiment. The capacitor is arranged on a substrate 30, which may include a semiconductor substrate, such as a silicon substrate. A voltage applied to the functional layer 32 and to the second functional layer 33 provokes an electric field in side the intermediate layer 21.

FIG. 1D illustrates a schematic view of an arrangement with a functional layer according to a fourth embodiment. According to this embodiment, a functional layer 42 is arranged between a first area 40 and a second area 41. The first area 40 may include a semiconductor, such as silicon. Furthermore, the first area 40 includes a material 49, such as a dopant. According to this embodiment, a diffusion of the material 49 from the first area 40 to the second area 41 is to be suppressed. The functional layer 42 acts as a diffusion area and hinders and/or obstructs the transfer of material 49 from the first area 40 to the second area 41.

The material 49, such as a dopant, may be comprised by the first area 40 in order to electrically functionalize the first area 40. For example, this may be the case for a doped region of a transistor, an electrode, a diode, a resistor, and/or a light emitting or sensing device. The diffusion of the material 49 to the second area 41 may affect the properties of the second area 41 and/or the first area 40. Also, tiny variations in a doping concentration may alter the electrical and/or optical properties of an affected area in such a way that the involved entity, for example a transistor, is rendered useless.

Since integrated devices usually are subject to a certain thermal budget during manufacturing, it may be necessary to take certain measures, such as the provision of the functional layer 42, in order to prevent an undesired diffusion of material during manufacturing. Furthermore, diffusion may take place and may affect the functionality and the performance of the device also during regular operation. Therefore, it may be again necessary to provide a diffusion barrier, such as the functional layer 42.

FIG. 1E illustrates an arrangement with a functional layer according to a fifth embodiment. According to this embodiment, a trench capacitor 59 is arranged in a substrate 50. The trench capacitor 59 may include electrodes and a dielectric material. Trench capacitors, such as the trench capacitor 59, are concepts of the technology of manufacturing integrated circuits. Particularly, the trench capacitor 59 may be, for example, a storage capacitor of a DRAM.

The arrangement further includes a collar 58 above the trench capacitor 59. The collar 58 includes an insulation collar 53, and a top contact, the top contact having a functional layer 52 and an inner electrode material 51. The inner electrode 51 may include a metal or doped poly-silicon. The electrode 51 may contact a center electrode of the trench capacitor 59 and/or a terminal of a selection transistor. According to this embodiment, the functional layer 52 may act as a liner or a collar liner of the collar 58.

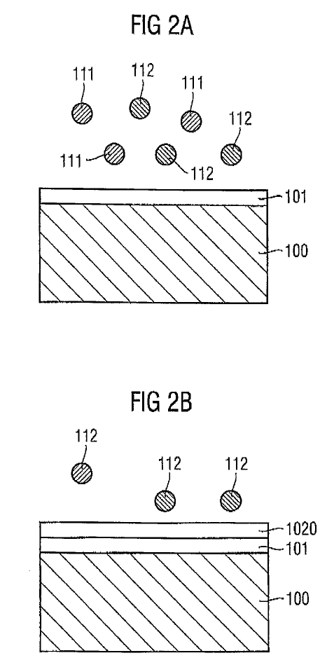

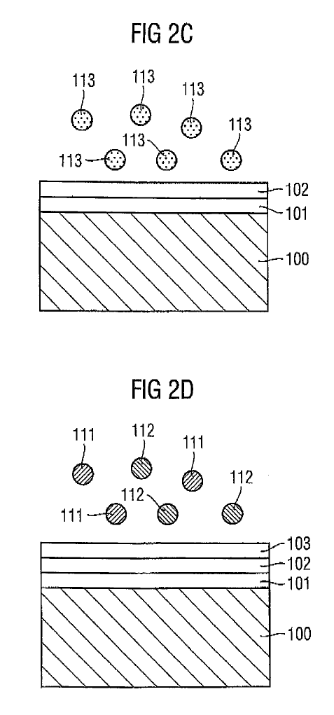

FIGS. 2A through 2D illustrate a functional layer, according to the first, the second, the third, the fourth, and/or the fifth embodiment of the present invention, in various stages during its fabrication. The fabrication of such a functional layer is seen as a sixth embodiment of the present invention.

FIG. 2A illustrates a functional layer being formed on a substrate 100 during a first stage of fabrication. The substrate 100 may include a semiconductor substrate, such as a silicon substrate, a dielectric layer, an isolation layer, an electrode layer, and/or any functionalized entity as they are known from the technology of fabricating integrated devices. The substrate 100 may further include three-dimensional or topological features, such as a trench, a step, a stack, a groove, a hole, a whisker, and/or a pillar.

Adjacent to the substrate 100 there is a process atmosphere which includes a first precursor 111 and a second precursor 112. The process atmosphere may be provided by using a process chamber and additional means for controlling the contents of the process atmosphere. Those means may include pumps, valves, flow-meters, vaporizers, gas tanks, plasma-producers, heaters, coolers, vacuum chambers, and/or handling equipment.

The first precursor 111 and the second precursor 112 may react to form a first partial layer 101 of the functional layer. This may be effected during a so called chemical vapor deposition (CVD) or metal-organic chemical vapor deposition (MOCVD). In general, during the provision of the functional layer, a substrate temperature of the substrate 100 may be in the range of 200° C. to 700° C. in order to influence, to enhance, or to activate the deposition or provision. The pressure of the process atmosphere may be in a range of 0.1 Torr to 10 Torr.

The first precursor 111 may include titanium-tetra-chloride (TiCl₄), titanium, titanium-chloride, zirconium, hafnium, niobium, tantalum, tungsten, fluorine, chlorine, bromine, iodine, a metal-alkyl-amide, a metal-organic (MO) precursor, and/or a metal halide. Metal-alkyl-amides may include a tantalum-alkyl-amide, such as TAIMATA, TBTEMT, TBTDET, IPTEMT, or PDMAT, a zirconium-alkyl-amide, such as TDMAZ, TEMAZ, or TDEAZ, or a hafnium-alkyl-amide, such as TDMAH, TEMAH, or TDEAH.

The second precursor 112 may include ammonia (NH₃), hydrogen, and/or nitrogen.

Reaction products may be continuously removed from the process atmosphere, for example, by purging with an inert gas, such as helium, neon, argon, krypton, xenon, and/or nitrogen.

As an example the first precursor 111 may include titanium-tetra-chloride (TiCl₄) and the second precursor 112 may include ammonia (NH₃). Reaction products, which may include in this case, chlorine and/or hydrogen, such as HCl, may be continuously removed from the process atmosphere, for example, by purging with an inert gas, such as helium, neon, argon, krypton, xenon, and/or nitrogen. In the case of TiCl₄ and NH₃, or a first precursor 111 including titanium, and the second precursor 112 including nitrogen, the first partial layer 101 may include titanium-nitride (TiN)

FIG. 2B illustrates a next stage of the fabrication of the functional layer. In this stage, the process atmosphere includes the second precursor 112. The first precursor 111 may have been removed from the process atmosphere by purging the process atmosphere or by pumping the entire process atmosphere, followed by a renewed provision of the second precursor 112.

Purging may be again effected by using an inert gas. Pumping the process atmosphere may be effected by providing a vacuum down to a residual pressure, the residual pressure being, for example, below 10⁻² mbar. During this stage a residual concentration in the process atmosphere of the first precursor 111, or of any other substance, may be allowable, such as a residual concentration which is below 5%. During this stage, a preliminary second partial layer 1020 of the functional layer is formed. The preliminary second partial layer 1020 may include the second precursor 112, such as ammonia. This may be effected during an atomic layer deposition (ALD) or a metal-organic atomic layer deposition (MOALD). During this stage, parts of the second precursor 112, such as nitrogen, may be incorporated into the first partial layer 101.

FIG. 2C illustrates a next stage of the fabrication of the functional layer. During this process stage, the process atmosphere includes a third precursor 113. The process atmosphere may have been purged or pumped prior to the provision of the third precursor 113 in the process atmosphere.

The third precursor 113 may include silicon, silane, silicon-chloride, silicon-tetra-chloride (SiCl₄), dichlorosilane, tetraethylorthosilicate, aluminum, titanium, zirconium, hafnium, niobium, tantalum, tungsten, fluorine, chlorine, bromine, iodine, a metal-alkyl-amide, an aluminum-alkyl-amide, silicon-alkyl-amide, tetrakis[dimethylamino]silane, tris[dimethylamino]silane, di[dimethylamino]silane, trimethylaluminum, TMA, and/or a metal-organic (MO) precursor. Metal-alkyl-amides may include a tantalum-alkyl-amide, such as TAIMATA, TBTEMT, TBTDET, IPTEMT, or PDMAT, a zirconium-alkyl-amide, such as TDMAZ, TEMAZ, or TDEAZ, a hafnium-alkyl-amide, such as TDMAH, TEMAH, or TDEAH, or an aluminium-alkyl-amide.

The provision of the third precursor 113 may be effected during an atomic layer deposition (ALD) or a metal-organic atomic layer deposition (MOALD), and the third precursor 113 may react with components of the preliminary second partial layer 1020 to form a second partial layer 102 of the functional layer. The second partial layer 102 may include a composite being formed by the second precursor 112 and the third precursor 113. In the case of ammonia and silicon-tetra-chloride, the second partial layer 102 may include silicon-nitride (SiN, Si₃N₄) and/or titanium-silicon-nitride (TiSiN). Reaction products, which may comprise, in this case, chlorine and/or hydrogen such as HCl, may be continuously removed from the process atmosphere, for example, by purging with an inert gas

FIG. 2D illustrates a next stage of the fabrication of the functional layer. Adjacent to the second partial layer 102 there is a process atmosphere which again includes the first precursor 111 and the second precursor 112, and a third partial layer 103 is formed. This may be effected during a so called chemical vapor deposition (CVD) or a metal-organic chemical vapor deposition (MOCVD). Since process precursors match those of the stage as described in conjunction with FIG. 2A, the third partial layer 103 may include the same components as those of the first partial layer 101, such as titanium, nitrogen, titanium-nitride, and/or titanium-silicon-nitride.

After the provision of the second partial layer 102 or after the provision of the third partial layer 103, the method may be continued with the formation of a further preliminary partial layer, a further second partial layer, and/or a further third partial layer, this formation being effected as has already been described in conjunction with FIGS. 2B through 2D. The method may be continued until a target thickness of the functional layer, including the deposited partial layers, has been reached. A target layer thickness of the functional layer may be in a range of 1 to 100 nm. The ready functional layer may include titanium-nitride, silicon-nitride, and/or titanium-silicon-nitride.

According to one embodiment, a deposition of titanium nitride, using a chemical vapor deposition process, employing titanium-tetra-chloride and ammonia, may be combined with an atomic layer deposition of silicon nitride, employing silicon-tetra-chloride and ammonia. In this way, the morphology, i.e. the roughness, the crystallinity and/or the texture of a titanium-nitride layer may be controlled by changing the number of intermediate silicon-nitride-deposition cycles. The thermal stability of the attained nitride, i.e. against surface oxidation and/or diffusion of oxygen and/or chlorine, may be controlled by changing the number of intermediate silicon-nitride deposition cycles.

Furthermore, it may be possible to conformally grow titanium-nitride and/or titanium-silicon-nitride onto a three-dimensional or topological feature, such as a trench, a step, a stack, a groove, a hole, a whisker, and/or a pillar, while keeping an optimized throughput and processes yield. Furthermore, it may be possible, to control the ratio of titanium to silicon in order to cover high aspect ratio structures, such as deep trenches or lean pillars. In this way, three-dimensional structures and features with an aspect ratio higher than 3 and/or higher than 10, may be covered conformal by a functional layer.

In addition to this, the content of chloride in a functional layer may be reduced, while still allowing for the desired physical and metallic or dielectric properties of the functional layer. The reduction of chlorine and/or other halogens may be of advantage, since halogens and/or precursors which include halogens are potentially hazardous substances, and are, in view of environmental aspects of the manufacturing process, to be reduced.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of fabricating an integrated circuit having a functional layer on a substrate, the method comprising:
providing a substrate in a process atmosphere;
providing a first precursor and a second precursor in the process atmosphere;
removing the first precursor from the process atmosphere;
removing the second precursor from the process atmosphere; and
providing a third precursor in the process atmosphere.

2. The method of claim 1, wherein the first precursor comprises at least one of a group consisting of titanium, titanium-chloride, or titanium-tetra-chloride, zirconium, hafnium, niobium, tantalum, tungsten, fluorine, chlorine, bromine, iodine, and a metal-alkyl-amide.

3. The method of claim 1, wherein the second precursor comprises at least one of a group consisting of nitrogen, hydrogen, and ammonia.

4. The method of claim 1, wherein the third precursor comprises at least one of a group consisting of silicon, silane, silicon-chloride, silicon-tetra-chloride, dichlorosilane, tetraethylorthosilicate, aluminum, titanium, zirconium, hafnium, niobium, tantalum, tungsten, fluorine, chlorine, bromine, iodine, a metal-alkyl-amide, an aluminum-alkyl-amide, trimethylaluminum, TMA, silicon-alkyl-amide, tetrakis[dimethylamino]silane, tris[dimethylamino]silane, and di[dimethylamino]silane, trimethylaluminum.

5. The method of claim 1, wherein the first precursor comprises titanium-tetra-chloride, wherein the second precursor comprises ammonia, and wherein the third precursor comprises silicon-tetra-chloride.

6. The method of claim 1, wherein the method comprises a chemical vapor deposition.

7. The method of claim 1, wherein the method comprises an atomic layer deposition.

8. The method of claim 1, wherein removing the first precursor from the process atmosphere comprises a purging of the process atmosphere with an inert gas.

9. The method of claim 1, wherein removing the second precursor from the process atmosphere comprises a purging of the process atmosphere with an inert gas.

10. The method of claim 1, comprising conducing the method until a target thickness of the functional layer is reached.

11. The method of claim 10, comprising wherein the method comprises purging the process atmosphere with an inert gas after providing a third precursor in the process atmosphere and prior to providing a first precursor and a second precursor in the process atmosphere.

12. The method of claim 1, comprising wherein a substrate temperature is in the range of 200° C. and 700° C.

13. The method of claim 1, comprising wherein a pressure of the process atmosphere is in the range of 0.1 Torr and 10 Torr.

14. The method of claim 1, comprising the functional layer being an electrode of a capacitor.

15. The method of claim 1, comprising the functional layer being an electrode of a metal-insulator-semiconductor capacitor.

16. The method of claim 1, comprising the functional layer being a diffusion barrier, the diffusion barrier obstructing the diffusion of a material from a first side of the diffusion barrier to a second side of the diffusion barrier.

17. The method of claim 1, comprising the functional layer being a collar liner of an isolation collar of a trench capacitor.

18. A method of fabricating a functional layer on a substrate, the method comprising:
providing a substrate in a process atmosphere;
providing a first precursor and a second precursor in the process atmosphere;
removing the first precursor from the process atmosphere; and
providing a third precursor in the process atmosphere.

19. The method of claim 18, wherein the first precursor comprises at least one of a group consisting of titanium, titanium-chloride, or titanium-tetra-chloride, zirconium, hafnium, niobium, tantalum, tungsten, fluorine, chlorine, bromine, iodine, and a metal-alkyl-amide.

20. The method of claim 18, wherein the second precursor comprises at least one of a group consisting of nitrogen, hydrogen, and ammonia.

21. The method of claim 18, wherein the third precursor comprises at least one of a group consisting of silicon, silane, silicon-chloride, silicon-tetra-chloride, dichlorosilane, tetraethylorthosilicate, aluminum, titanium, zirconium, hafnium, niobium, tantalum, tungsten, fluorine, chlorine, bromine, iodine, a metal-alkyl-amide, an aluminum-alkyl-amide, trimethylaluminum, TMA, silicon-alkyl-amide, tetrakis[dimethylamino]silane, tris[dimethylamino]silane, and di[dimethylamino]silane, trimethylaluminum.

22. The method of claim 18, wherein the first precursor comprises titanium-tetra-chloride, wherein the second precursor comprises ammonia, and wherein the third precursor comprises silicon-tetra-chloride.

23. The method of claim 18, wherein the method comprises a chemical vapor deposition.

24. The method of claim 18, wherein the method comprises an atomic layer deposition.

25. The method of claim 18, wherein removing the first precursor from the process atmosphere comprises a purging of the process atmosphere with an inert gas and a providing of the second precursor in the process atmosphere.

26. The method of claim 18, comprising conducing the method until a target thickness of the functional layer is reached.

27. The method of claim 26, wherein the method comprises a purging of the process atmosphere with an inert gas after providing a third precursor in the process atmosphere and prior to providing a first precursor and a second precursor in the process atmosphere.

28. The method of claim 18, comprising wherein a substrate temperature is in the range of 200° C. and 700° C.

29. The method of claim 18, comprising wherein a pressure of the process atmosphere is in the range of 0.1 Torr and 10 Torr.

30. The method of claim 18, comprising the functional layer being an electrode of a capacitor.

31. The method of claim 18, comprising the functional layer being an electrode of a metal-insulator-semiconductor capacitor.

32. The method of claim 18, comprising the functional layer being a diffusion barrier, the diffusion barrier obstructing the diffusion of a material from a first side of the diffusion barrier to a second side of the diffusion barrier.

33. The method of claim 18, comprising the functional layer being a collar liner of an isolation collar of a trench capacitor.
